(19) United States
(12) Patent Application Publication
(10) Pub. No.: US 2015/0130463 A1
(43) Pub. Date: May 14, 2015

(54) PORTABLE DEVICE FOR NMR BASED ANALYSIS OF RHEOLOGICAL CHANGES IN LIQUID SAMPLES

(71) Applicant: T2 Biosystems, Inc., Lexington, MA (US)

(72) Inventors: Parris S. Wellman, Reading, MA (US); Matthew Blanco, Brookline, MA (US); William Peine, Ashland, MA (US)

(73) Assignee: T2 BIOSYSTEMS, INC., Lexington, MA (US)

(21) Appl. No.: 14/406,394

(22) PCT Filed: Jun. 25, 2013
(86) PCT No.: PCT/US13/47703

§ 371 Date: Dec. 8, 2014

Related U.S. Application Data
(60) Provisional application No. 61/663,768, filed on Jun. 25, 2012.

(51) Int. Cl. G01R 33/30

(52) U.S. Cl. CPC G01R 33/30
USPC 324/321

(57) ABSTRACT

The invention features a portable device for monitoring changes in the rheological state of multiple samples by NMR based measurement. The rheological changes can be, for example, gelation occurring during limulus amoebocyte lysate (LAL) testing for endotoxins or blood coagulation. The inventive method entails organization of individual NMR tubes in a disposable cartridge where the tubes are connected through a top cover, provided with movable actuators to push the reagent in the reagent compartments of the individual chambers to the reaction chambers in a predetermined sequence.

### CROSS-REFERENCE TO RELATED APPLICATIONS

This application claims benefit of U.S. Provisional Application No. 61/663,768, filed Jun. 25, 2012, which is hereby incorporated by reference in its entirety.

### BACKGROUND OF THE INVENTION

The present invention features a disposable cartridge and a portable device for monitoring changes in the rheological state of multiple samples by NMR based measurement. The rheological changes can be, for example, gelation occurring during limulus amoebocyte lysate (LAL) testing for endotoxins or blood coagulation.

Endotoxin is a component of the cell wall in the outer membrane of gram-negative bacteria, and its activity is mainly attributed to LPS (lipopolysaccharide). In the living body, endotoxin exists as a part of the outer membrane in the surface layer of gram negative bacteria. Generally, after death of gram-negative bacteria, endotoxin is liberated and is present in a free form in blood.

When more than a certain level of endotoxin is present in blood, the endotoxin stimulates monocytes, granulocytes, etc., resulting in excessive production of inflammatory cytokines. Consequently, so called endotoxinemia accompanied by symptoms such as fever, sepsis, septic shock, multiple organ failure, etc. is induced. For this reason, detection of endotoxin in pharmaceuticals for injection, etc. is crucial, and thus the bacterial endotoxin test is prescribed by the Japanese, U.S., and European pharmacopeias. From the aspect of clinical diagnosis, precise measurement of blood endotoxin level is considered crucial for early diagnosis and therapeutic effect evaluation.

Examples of a conventional method for measuring endotoxin include the pyrogen test, in which a rabbit is treated with a direct injection of a test sample and measured for increase in body temperature that can be converted into the endotoxin level, and the Limulus test utilizing gelation of horseshoe crab amebocyte lysate triggered by endotoxin. The method involving direct injection into a rabbit has problems in cost, length of time required to obtain the test results, and sensitivity, and for this reason, the Limulus test currently prevails as a method for measuring endotoxin.

A gelation of horseshoe crab amebocyte lysate is triggered by endotoxin. The gelation process of horseshoe crab amebocyte lysate contains a Factor-C pathway specifically associated with endotoxin. The Factor-C pathway is constituted by the following cascades. First, endotoxin firmly binds with Factor-C, and thereby activates the Factor-C. Then, Factor-C activated by binding with endotoxin (active Factor-C) activates Factor B. Subsequently, activated Factor B (active Factor B) activates a proclotting enzyme, resulting in production of a clotting enzyme. This clotting enzyme partially hydrolyzes its substrate, i.e., coagulogen. As a result, peptide C is liberated from the coagulogen, and a clotting protein, coagulin, is produced. By a coagulation action of the coagulin, gelation occurs.

The Limulus test for measuring endotoxin utilizes the above-mentioned gelation process of Limulus amebocyte lysate (LAL) triggered by endotoxin. As the Limulus test, a gel-clot technique, a colorimetric technique using synthetic chromogenic substrates, and a kinetic turbidimetric techniques are established techniques used to evaluate gelation.

Blood is the circulating tissue of an organism that carries oxygen and nutritive materials to the tissues and removes carbon dioxide and various metabolic products for excretion. An accurate measurement of hemostasis, i.e., the ability of a patient's blood to coagulate and dissolve, in a timely and effective fashion is crucial to certain surgical and medical procedures. Accelerated (rapid) and accurate detection of abnormal hemostasis is also of particular importance in respect of appropriate treatment to be given to patients suffering from hemostasis disorders and to whom it may be necessary to administer anticoagulants, antifibrinolytic agents, thrombolytic agents, anti-platelet agents, or blood components in a quantity which must clearly be determined after taking into account the abnormal components, cells or “factors” of the patient's blood which may be contributing to the hemostasis disorder.

New devices and methods of detection are needed that can (i) increase the limit of detection of endotoxin, (ii) reduce the about of amebocyte lysate required for performing the assay, (iii) allow for the monitoring of samples containing light scattering compositions, (iv) allow for the monitoring of samples using T2 relaxation times, (v) allow for continuous monitoring of blood hemostasis at points of care and (vi) be available for use as portable devices at points-of-care for rapid endotoxin and hemostasis analysis.

### SUMMARY OF THE INVENTION

The present invention features a disposable cartridge and a portable device for monitoring changes in the rheological state of multiple samples by NMR based measurement. The cartridge and device of the invention can be used to measure changes in viscosity, gelation, coagulation, and rheological state of liquid samples. The rheological changes can be, for example, gelation occurring during limulus amoebocyte lysate (LAL) testing for endotoxins, blood coagulation testing, or for any other use described herein.

In a first aspect, the invention features a disposable cartridge sized for convenient insertion into and removal from a slot of a portable magnetic resonance device including: a) a plurality of chambers (e.g., 1, 2, 3, 4, 5, 6, 7, 8, 9, or 10 chambers, optionally arranged in one or more rows), wherein for each of the plurality of chambers the chamber includes (i) a sample chamber, (ii) a test chamber, and (iii) a barrier separating the sample chamber and the test chamber, wherein for at least one test chamber among the plurality of chambers includes a testing reagent; b) a sample input port for receiving a liquid sample, wherein for one or more of the plurality chambers, the sample input port is in fluid communication with the sample chamber; and c) a top cover for holding the plurality of chambers, wherein for each of the the plurality of chambers the top cover includes a moveable member, wherein movement of the moveable member from a first position to a second position opens the barrier and mixes the contents of the sample chamber and the test chamber. In particular embodiments, the chambers are cylindrical in shape and optionally include a flat bottom.

In one embodiment, the cartridge includes a sample input port is connected to each of the plurality of chambers by a fluidic channel configured to distribute equal volume of sample from the input port into each sample chamber. In another embodiment, the cartridge includes a plurality of sample input ports for receiving a plurality of samples, wherein for each of the plurality of sample input ports a single sample input port is connected to a single sample chamber by a fluidic channel.

The cartridge can further include a reservoir for holding a testing reagent, wherein the reservoir is in fluid communication with one or more of the plurality of chambers. For example, the reservoir can be connected to a single sample chamber by a fluidic channel which is configured to permit passage of the testing reagent into the sample chamber at a predetermined time.

The testing reagent in the test chamber of the cartridge may be an endotoxin testing reagent, e.g., a limulus amoebocyte lysate. Alternatively, the testing reagent can be a blood clotting initiator or a blood clotting inhibitor (e.g., CaCl₂, A-P1, or a mixture of ADP-P2 and A-P1).

The chambers of the cartridge can have a volume of 1 μL to 150 μL (e.g., from 2 to 10 μL, 10 μL to 20 μL, 15 μL to 50 μL, 50 μL to 100 μL, 100 μL to 150 μL).

In one particular embodiment, the cartridge further includes a lid, wherein for each of the plurality of sample chambers closing of the lid results in a movement of the moveable member to a position causing the barrier to open.

In certain embodiments of the cartridge, a frangible membrane seal separates the sample chamber and the test chamber, and movement of the moveable member from a first position to a second position breaks the frangible membrane seal and mixes the contents of the sample chamber and the test chamber. For example, the moveable member can include a protrusion for puncturing the frangible membrane. Alternatively, the moveable member can include a plunger for applying pressure to and breaching the frangible membrane.

In particular embodiments of the cartridge, a first testing reagent is immobilized on the frangible membrane and a second testing reagent is located within the test chamber.

In certain embodiments, the cartridge can be a staged cartridge that includes a tube having multiple test chambers, each separated from at least one other test chamber by a frangible membrane. Each tube of the cartridge can permit a single sample to pass serially, in stages, through the multiple test chambers. Each test chamber can be used to stage an assay performed on the sample. For example, the first stage permits detection of an NMR relaxation response on a sample treated with a first reagent in the first test chamber; the second stage permits detection of an NMR relaxation response on the contents of the first test chamber mixed with a second reagent in the second test chamber, the third stage permits detection of an NMR relaxation response on the contents of the second test chamber mixed with a third reagent in the third test chamber, and so forth. Optionally, the staged cartridge is equipped with multiple RF coils, one for each test chamber present in each tube of the cartridge. The staged cartridge can be used to monitor in series a sample prior to any rheological change (e.g., gelation or clotting), after a first rheological change has occurred in the sample, and after after a second rheological change has occurred in the sample (e.g., dissolution of a clot, or a change in clot type).

In a related aspect, the invention features a portable magnetic-resonance device for measuring a change in the rheological state of a sample. The device includes an RF excitation coil for transmitting an RF excitation to a plurality of liquid samples; a slot for receiving a cartridge of the invention including a plurality of liquid samples; for each liquid sample an RF receiver coil disposed about the liquid sample and configured to detect an NMR relaxation response produced by exposing a liquid sample to a bias magnetic field created using the permanent magnet and the RF excitation; a timer; a lid; and, optionally, a touch-screen LCD panel for displaying device control parameters and/or test results.

Once a cartridge containing a plurality of liquid samples is placed into the slot in the device, the device lid is shut. This results in moving of the movable member of the cartridge and opening the barrier separating the sample chamber and the test chamber. This causes contact/mixing between the sample and, optionally, a testing reagent. The timer of the device is configured to be activated when the barrier is opened. Activation of timer initiates measurement of a NMR relaxation response characteristic of a change in a rheological state of the liquid sample.

In particular embodiments of the device, the RF coil disposed about the liquid sample is configured to serve as the RF excitation coil (i.e., one coil serves both functions for each liquid sample). In other embodiments, for each of the chambers, the RF coil disposed about the liquid sample is contained within the cartridge. Alternatively, for each of the chambers, the RF coil disposed about the liquid sample may not be contained within the cartridge.

The device can further include a heater for heating one or more of the plurality of chambers (e.g., heating to a predetermined temperature to assess the impact of temperature on the rheology, or rate of change in rheology for a given sample).

The liquid sample to be used with the cartridge and device of the invention can be any one of whole blood, plasma, or any turbid, opaque, or clear liquid sample (e.g., a pharmaceutical solution or suspension, or suspensions/solutions of food samples).

The device of the invention can be used to measure changes in viscosity, crystallization, gelation, coagulation, and rheological state of any liquid sample. For example, in the field of petroleum products, the devices of the invention may be used to monitor asphalt/bitumen, bitumen-polymer manufacture, boiler, crude oil, coal ash, coal slurry, cracking, distillation residues, engineering, fluxed bitumen, high viscosity oil, furnace oils, lubricant, mixing fuel oils, oil additives, oil clarificator, blending oils, oils counters (pipeline terminal), oils wear control, plastisols, mineral oils, petroleum additives manufacture, petroleum products, pipe line counters, pitch coating, pitch dilution, pumping of Erika disaster, quench oil, residues transfoimation in fuel oils, separation of water, sediment and oils, special oils, synthetic rubber, tar control before use, very heavy oil, and water-coal slurries. In the field of coatings and paint, the devices of the invention may be used to monitor car paint, metallic paint, water paint, special ink for scraping game, special ink for aluminum or plastic surfaces, water ink, PTFE coating, white paper coating, special paper coating, wall paper, glue, varnish, car varnish, special paint for engines, manufacture of ink, photogravure, dye, print board varnish, magnetic ink, magnetic varnish, gloss paint, silvering for mirrors, special varnish for spectacles, and enamel powder. In the field of food and beverages, the devices of the invention may be used to monitor bechamel sauce manufacture, bread manufacture, chocolate manufacture, dough control, fermentation control, fish solubles (evaporation control), fresh cheese manufacture, gelatin food concentration, ice creams manufacture, jam manufacture, margarine manufacture, mayonnaise manufacture, melted cheese manufacture, milk and cheese research, paraffin coating control, proteins concentration control, proteins for animal food, seaweed gelatin, slop control, stewed fruit, sugar boilers (crystallization control), sugar mixer, surimi paste, synthetic flavors, tomato sauce, vegetable margarine and oil, yeasts, yogurt, beer/yeast Control, dough in a bakery, food additives, gelatins (proteins concentration), milk atomization, yogurt, processed cheese, sweetened juice, salad sauce, food thickener, food additives, enzymes concentration control, freezing fluid control artificial food flavor, tobacco liquor, residual sugar liquor, industrial soups, pudding, milk powder, pet food, livestock food, baby food, evaporated milk, starch gel, fruit paste, and fruit juice. In the field of industrial chemistry, the devices of the invention may be used to monitor basic resins for paints manufacture, polymer, polymer-bitumen manufacture, polymerization control, polycarbonate, PVC Production, two components resins, fibers and polymers, cable resin, epoxy resin, polyamide resins, chloral methyl resins, PVC, carboxyl methyl cellulose, hydrochloric acid, urethane glue, toluene diisocyanate, MEK toluene, plastic recycling, silicone oils, paste, glue, PBU, ethanol toluol, polycarbonate, polyester resins manufacture, polyether polyol control, polyisobutylene, polymer resins manufacture, polymerised vinyl+toluene, polymerization industry, resins polymerization of silicones oils, unsaturated polyester resin, urea-formol resin, glue, polyamide resin, nylon, polypropylene resin, polyethylene, epoxy resin, polyephine wax, dimethyl acetate, phenolic resin, plaster, melamine, and methyl methacrylate. The devices of the invention may also be used to monitor biochemical products, cellulose acetates, fabric softener, enzymes, gel coatings, pharmaceutical capsules, aerosols, chemicals manufacturing (washing bases), cosmetics manufacture and control, creams, engineering in cosmetics machines, fermentation control, glasses for spectacles, pharmaceuticals, photographic emulsions, shampoo manufacture, tooth paste, UV sensitive varnishes, viscosity control in emulsion, vitamin A, photographic emulsions, videotapes, gels, emulsions, delicate chemistry, fluorescent paste for lighting, hydraulic oils, latex atomization, UV glue, hot melt glue, drilling mud, plastisols, acid concentration, mercury, accumulator acid, detergent, ceramic, slurries, glue, adhesive polymer, calcium carbonate, acrylic glue, lime milk, ammonia+MCB+oil, high viscosity combustible fuels, crude oil counting, mixing of two oils, lubricant oils, animal fat boiler, fuel oil, wastewater concentration, mud concentration, yeast sludge, oil contamination, solvent contamination, distressing control of oil, quench oil, cutting oil, and processes involving a setting tower. The devices of the invention can be used as a lead compound and compound validation discovery tool. The devices of the invention can identify variations in the coagulation cascade as a function of intervention in the cascade by one or more candidate compounds, or identify variations outside the coagulation cascade (e.g., platelet morphology) in response to candidate compounds. The devices and devices of the invention can be used to screen compound libraries to identify active agents, as well as pinpoint new mechanisms for disease and treatment. These are likely to be in the coagulation cascade, but many will be targets not usually defined or identified in the cascade. This approach can also be used to identify disease states that are differentiated from known coagulation disorders.

As used herein, the term “magnetic resonance parameter” refers to a relaxation rate or amplitude extracted from an NMR relaxation rate measurement. As used herein, the NMR relaxation data is selected from T1, T2, T1/T2 hybrid, T₁ᵣₕₒ, T₂ᵣₕₒ, and T₂* data.

As used herein, the term “T1/T2 hybrid” refers to any detection method that combines a T1 and a T2 measurement. For example, the value of a T1/T2 hybrid can be a composite signal obtained through the combination of, ratio, or difference between two or more different T1 and T2 measurements. The T1/T2 hybrid can be obtained, for example, by using a pulse sequence in which T1 and T2 are alternatively measured or acquired in an interleaved fashion. Additionally, the T1/T2 hybrid signal can be acquired with a pulse sequence that measures a relaxation rate that is comprised of both T1 and T2 relaxation rates or mechanisms.

As used herein, the term “T2 signature” refers to a curve established by applying a mathematical transform (e.g., a Laplace transform or inverse Laplace transform) to a decay curve associated with a relaxation rate parameter at a discrete time point or over a set time duration during a rheological event. T2 signature curves provide information about the relative abundance of multiple water populations in a clot. As clotting or fibrinolysis progresses, the T2 signature curves will reflect the changes within the clot. T2 signatures may be used advantageously to assess, in real time, a discriminated hemostatic condition of a subject. Further, a T2 signature may be a two dimensional (intensity versus T2 value or T2 value versus time) or three dimensional representation (intensity versus T2 value versus time). The T2 values in the two- or three dimensional representation may be replaced with or compared to other NMR signals such as T1, T1/T2 hybrid, T₁ᵣₕₒ, T₂ᵣₕₒ and T₂*.

As used herein, the term “a first water population” refers to a water population of an aqueous sample that is characterized by an initial amplitude when unclotted that changes with gelation or clotting. A first water population may also refer to a water population referred to elsewhere in the application as population A. The amplitude and T2 data extracted from a first water population are referred to as Amp_{A} and T2A, respectively.

As used herein, the term “whole blood” refers to the blood of a subject that includes red blood cells. Whole blood includes blood which has been altered through a processing step or modified by the addition of an additive (e.g., heparin, citrate, a nanoparticle formulation, fibrinogen, tissue plasminogen activator (TPA), collagen, antithrombotic agents such as abciximab, or other additives).

As used herein, the term “a second water population” refers to a water population of an aqueous sample that is characterized by an initial amplitude when unclotted that changes with gelation or clotting. The second water population having a characteristic relaxation time that is different from the first water population. The second water population may be referred to elsewhere in the application as population B. The amplitude and T2 data extracted from a second water population are referred to as Amp_{B} and T2B, respectively.

As used herein, the term “algorithm” refers to a mathematical routine used to process or transform data.

As used herein, the term “LAL reagent” refers both to amebocyte lysates obtained from horseshoe crabs (e.g., Limulus polyphemus, Carcinoscorpius rotundicauda, Tachypleudus tridentata, or Tachypleudus gigas) and to synthetic LAL reagents. Synthetic LAL reagents include, for example, can include purified horseshoe crab Factor-C protein (naturally occurring or recombinant) and, optionally, a surfactant, as described in WO 03/002976. One such reagent, “PyroGene™,” is available from Cambrex Bio Science Walkersville, Inc. Reagents, such as those discussed in U.S. Patent Publication No. 20030054432, can also be used. LAL reagents preferably can be obtained from Cambrex Bio Science Walkersville, Inc. Lyophilized LAL reagent can be reconstituted with 1.4 mL of LAL reagent water (endotoxin-free water) and kept refrigerated until use. A reagent kit that enables highly sensitive measurement of endotoxin using a recombinant Factor-C (trade name: PyroGene rFc, manufacturer: Lonza Walkersville, Inc., distributor: Daiichi Pure Chemicals Co., Ltd.) is commercially available.

Other features and advantages of the invention will be apparent from the following Detailed Description, the drawings, and the claims.

### BRIEF DESCRIPTION OF THE DRAWINGS

FIG. 1A is an image showing the portable NMR device for endotoxin analysis and the removable cartridge outside of the device. FIG. 1B is an image showing the cartridge inserted into the slot in the device, but with the device lid open. FIG. 1C is an image with the cartridge inserted into the slot in the device, and the device lid closed. Mixing between the sample and testing reagents is initiated by closing the lid. Closing the lid also initiates a timer and the measurement of NMR relaxation rates. The test result is then displayed on a touch-screen LCD on the front of the instrument.

FIG. 2A is a representative image of the removable cartridge with four chambers and one sample input port on the top cover. FIG. 2B is an image showing a cross-sectional view of the removable cartridge shown in FIG. 2A.

FIG. 3 is a representative image of the removable cartridge with three chambers and three sample input ports on the top cover.

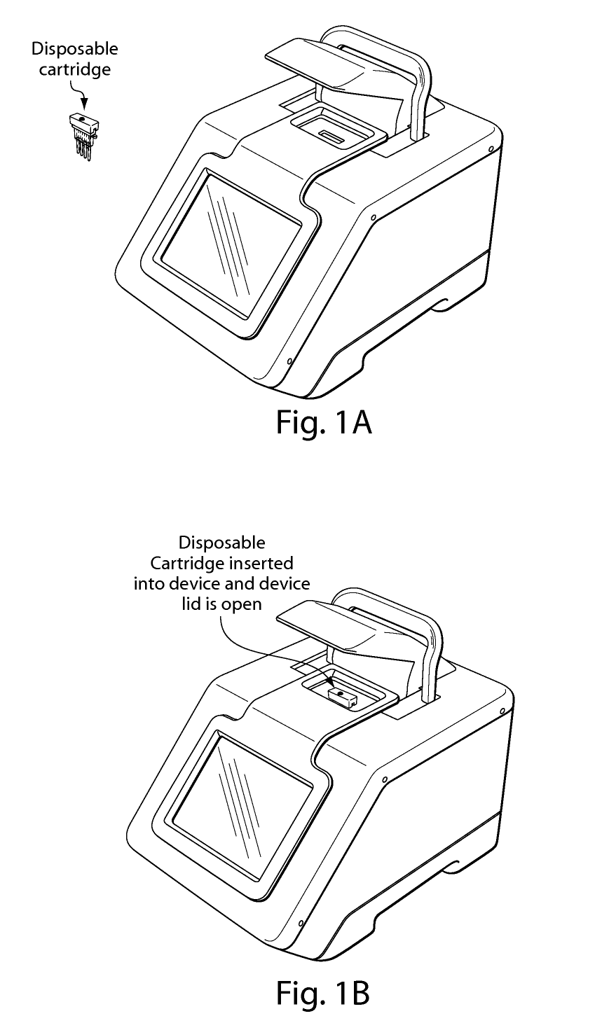

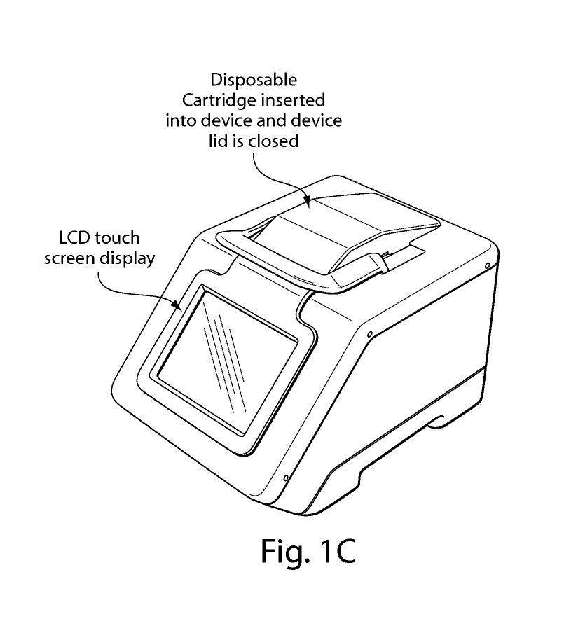

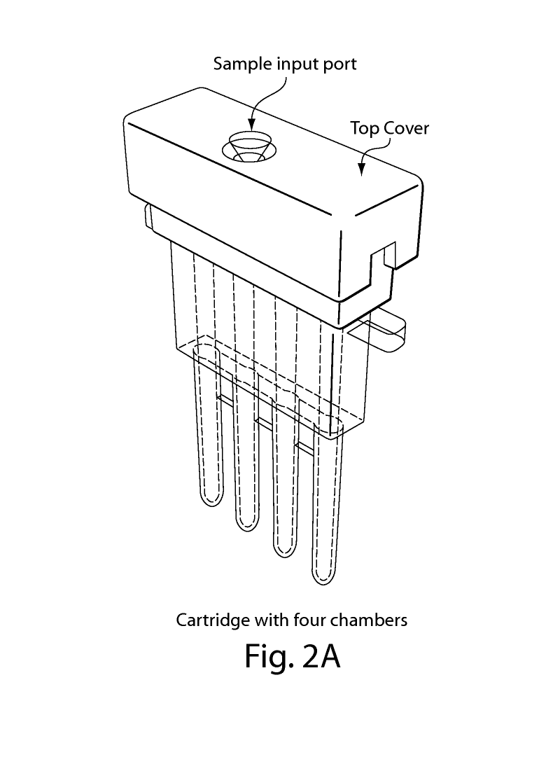

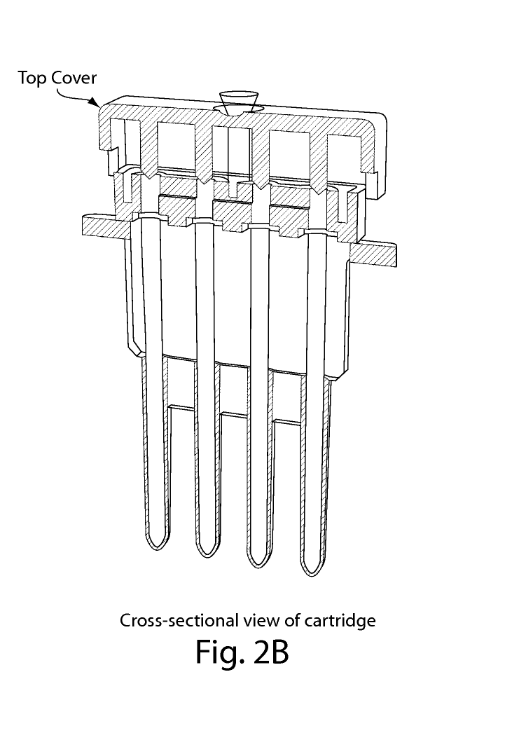

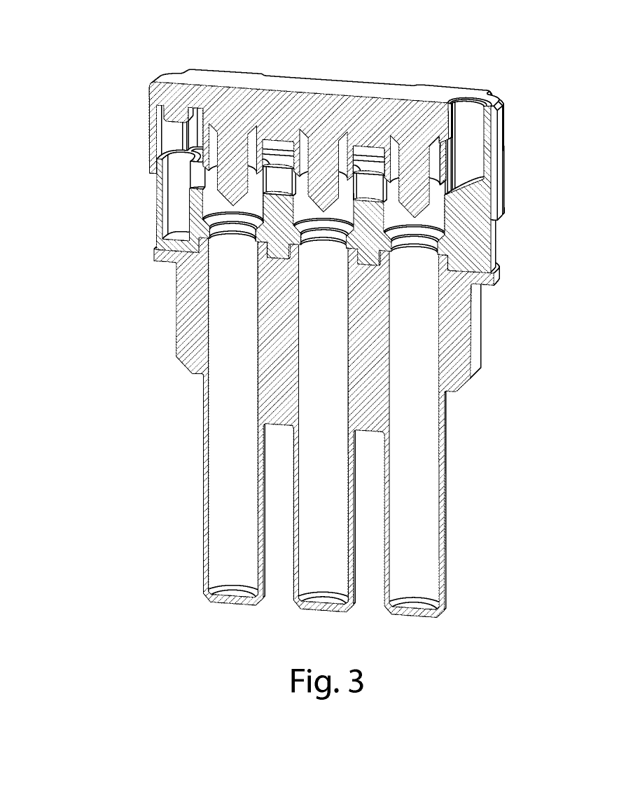

### DETAILED DESCRIPTION

The present invention relates to a disposable cartridge and a portable NMR device for analysis of changes in the rheological state of samples.

### Portable NMR Device

The invention features a portable NMR device for rapid detection of rheological changes in liquid samples, for example, monitoring of LAL testing for endotoxin analysis or monitoring blood coagulation in a blood sample from a human subject. For example, the device can contain a housing that has: a permanent magnet defining a magnetic field; one or more RF excitation coils for transmitting an RF excitation to each of the samples; and a slot for receiving a disposable cartridge containing one or more sample chambers. The device includes one or more RF receiver coils that surround individual sample chambers of the inserted cartridge (the RF receiver coils optionally located in the cartridge), and configured to detect an NMR relaxation response produced by exposing a liquid sample to a bias magnetic field created using the permanent magnet and the RF excitation. The device also includes a timer; a lid; and, optionally, a touch-screen LCD for displaying device control parameters and test results. In particular embodiments, the RF excitation coils and RF′ receiver coils are one and the same. Additional details can be found in U.S. Pat. No. 7,564,245, and in PCT Publication No. WO2012054639, published Apr. 26, 2012, each of which is incorporated herein by reference. For staged cartridges the housing can be equipped with multiple RF coils, one for each test chamber present in each tube in the cartridge. Alternatively, one RF coil is provided for each tube of the staged cartridge, and either the cartridge or the RF coil is moveable to permit the one RF coil to be positioned to measure an NMR response for each test chamber as the sample moves from stage to stage within a tube of the cartridge.

When the samples come in contact with a testing reagent, a gelation/clotting reaction is initiated in the sample. The device can measure the kinetics of the rheological changes in the samples by measuring changes in NMR relaxation signals that are characteristic of: hypocoagulability or hypercoagulability in case of blood samples; or the presence or absence of endotoxins in case of LAL testing.

The measurements can be done in parallel with and relative to control samples. The results are displayed on the touch-screen LCD. The device may also include a microprocessor that can perform an algorithm using the raw NMR data and display signature curves that are characteristic of the presence or absence of endotoxins or the theological state of the clotting blood sample.

The cartridge and device of the invention can be used to make multiple NMR measurements of a sample to detect changes in the rheological state of the sample caused by addition of reagents (e.g., one or more testing reagents), or by changing the physical environment of the sample (e.g., change in temperature of sample). For example, a first NMR measurement can be made before the sample is mixed with the testing reagent, and a second NMR measurement can be made after mixing of sample and testing reagent. Alternatively, the sample chamber can be further divided by a barrier into an upper holding chamber in fluid communication with the sample input port and a sample chamber that is in communication with the frangible membrane. A first testing reagent can be immobilized on the frangible membrane, and a second testing reagent can be within the testing chamber below the frangible membrane. This configuration allows for a first NMR measurement to be made in the holding chamber, followed by downward movement of the sample and contact with the first testing reagent on the frangible membrane. A second NMR measurement is made after mixing of sample and first testing reagent. Next, the frangible membrane is broken and the sample is mixed with the second testing reagent in the testing chamber. A third NMR measurement is made after mixing of sample with the second testing reagent.

The cartridge of the invention can also feature a plurality of conduits that are in fluid communication with a reservoir containing a test reagent and the sample and testing chambers. The conduits allow the delivery of specific volumes of testing reagents to the sample/testing chambers at designated times. Generally, a conduit has an inlet and an outlet. The inlet and/or outlet need not be discrete structures but may designate reference conduit sites, e.g., through or past which liquid reagents may flow. A testing reagent may be driven through a conduit either actively, e.g., by a fluidic actuation device, or passively, e.g., by gravity or capillary action. The conduits may optionally be configured to receive a fluid actuation device. Such devices include, e.g., a vacuum source, a vacuum pump, a peristaltic pump, or a syringe pump. Fluidic actuation devices may be capable of generating a plurality of flow rates, and allow the transport of a testing reagent from a reservoir to the appropriate downstream chamber, e.g., the sample chamber, or the testing chamber at a designated time. Detailed description of conduits and their design and uses in NMR devices are provided in International application No. PCT/US2011/56867, filed Oct. 19, 2011, and incorporated herein by reference. The reservoir containing a testing reagent may be part of the disposable cartridge. Alternatively, the reservoirs containing the testing reagents may be part of the device and may form a fluid communication with the sample and/or testing chamber via the conduits when the cartridge is inserted into the device.

The device of the invention may also include a temperature control element to expose one or more samples in the cartridge to a plurality of temperatures. This would allow detection of changes in the rheological state of a sample in response to changes in the temperature of the sample. For example, the device may include a heating element that can change the temperature of all samples in a cartridge, and cycle through a pre-programmed set of temperatures in between or during NMR measurements. Alternatively, the device may include a plurality of zones including thermally conductive material, such that the temperature of each zone is maintained or modulated independently of the other zones. Such a configuration would be useful when a sample/testing chamber of the cartridge is moved into a specific temperature zone and would allow NMR measurements of that sample alone at a specific temperature.

### Signal Acquisition and Processing in the Portable Device

Standard radiofrequency pulse sequences for the determination of nuclear resonance parameters are known in the art, for example, the Carr-Purcell-Meiboom-Gill (CPMG) is traditionally used if relaxation constant T₂ is to be determined. Optimization of the radiofrequency pulse sequences, including selection of the frequency of the radiofrequency pulses in the sequence, pulse powers and pulse lengths, depends on the system under investigation and is performed using procedures known in the art.

Nuclear magnetic resonance parameters that can be obtained using the device of the present invention include but are not limited to T1, T2, T1/T2 hybrid, T₁ᵣₕₒ, T₂ᵣₕₒ and T₂*. Typically, at least one of the one or more nuclear resonance parameters that are obtained using the device of the present invention is spin-spin relaxation constant T2.

As with other diagnostics and analytical instrumentation, the goal of NMR-based diagnostics is to extract information from a sample and deliver a high-confidence result to the user. As the information flows from the sample to the user it typically undergoes several transformations to tailor the information to the specific user.

For example, NMR relaxation data, such as T2, can be fit to a decaying exponential curve defined by the following equation:

$$f ( t ) = {\sum }_{i = 1}^{n} {A}_{i} exp ( \frac{- t}{T ( i )} ) \qquad ( 3 )$$

where ƒ(t) is the signal intensity as a function of time, t, Aᵢ is the amplitude coefficient for the ith component, and (T)ᵢ the decay constant (such as T2) for the ith component. For relaxation phenomenon discussed here the detected signal is the sum of a discrete number of components (i=1, 2, 3, 4 . . . n). Such functions are called mono-, bi-, tri-, tetra- or multi-exponential, respectively. Due to the widespread need for analyzing multi-exponential processes in science and engineering, there are several established mathematical methods for rapidly obtaining estimates of Aᵢ and (T)ᵢ for each coefficient. Methods that have been successfully applied and may be applied in the processing of the raw data obtained using the methods of the present invetion include Laplace transforms, algebraic methods, graphical analysis, nonlinear least squares (of which there are many flavors), differentiation methods, the method of modulating functions, integration method, method of moments, rational function approximation, Padé-Laplace transform, and the maximum entropy method (see Istratov, A. A. & Vyvenko, O. F. Rev. Sci. Inst. 70:1233 (1999)). Other methods, which have been specifically demonstrated for low field NMR include singular value decomposition (Lupu, M. & Todor, D. Chemometrics and Intelligent Laboratory Systems 29:11 (1995)) and factor analysis.

There are several software programs and algorithms available that use one or more of these exponential fitting methods. One of the most widely cited sources for exponential fitting programs are those written and provided by Stephen Provencher, called “DISCRETE” and “CONTIN” (Provencher, S. W. & Vogel, R. H. Math. Biosci. 50:251 (1980); Provencher, S. W. Comp. Phys. Comm. 27:213 (1982)). DISCRETE is an algorithm for solving for up to nine discrete components in a multi-component exponential curve. CONTIN is an algorithm that uses an inverse Laplace transform to solve for samples that have a distribution of relaxation times. Commercial applications using multiexponential analyses use these or similar algorithms. In fact, Bruker minispec uses the publicly-available CONTIN algorithm for some of their analysis. For the invention described here, the relaxation times are expected to be discrete values unique to each sample and not a continuous distribution, therefore programs like CONTIN are not needed although they could be used. The code for many other exponential fitting methods are generally available (Istratov, A. A. & Vyvenko, O. F. Rev. Sci. Inst. 70:1233 (1999)) and can be used to obtain medical diagnostic information according to the methods of the present invention. Information is available regarding how the signal to noise ratio and total sampling time relates to the maximum number of terms that can be determined, the maximum resolution that can be achieved, and the range of decay constants that can be fitted. For a signal to noise ratio of ˜10⁴ the theoretical limit as to the resolution of two decay constants measured, independent of the analytical method, is a resolution δ=(Tᵢ/Tᵢ₊₁) of >1.2 (Istratov, A. A. & Vyvenko, O. F. Rev. Sci. Inst. 70:1233 (1999)). Thus it is believed that the difference between resolvable decay constants scales with their magnitudes, which is not entirely intuitive and is unlike resolution by means of optical detection. The understanding of the maximum resolution and the dependence on resolution on the signal-to-noise ratio will assist in assessing the performance of the fitting algorithm.

The CPMG pulse sequence used to collect data with a T2 reader is designed to detect the inherent T2 relaxation time of the sample. Typically, this is dictated by one value, but for samples containing a complex mixture of states (e.g., a sample undergoing a clotting process or dissolution process), a distribution of T2 values can be observed. In this situation, the signal obtained with a CPMG sequence is a sum of exponentials. One solution for extracting relaxation information from a T2 reader output is to fit a sum of exponentials in a least-squares fashion. Practically, this requires a priori information on how many functions to fit. A second solution is to use the Inverse Laplace transform (ILT) to solve for a distribution of T2 values that make up the exponential signal observed. Again, the results of the CPMG sequence S(t), is assumed to be the sum of exponentials

$$S ( t ) = {\sum }_{i} {A}_{i} {e}^{- t / T {2}_{i}} \qquad ( 4 )$$

Where Aᵢ is the amplitude corresponding to the relaxation time constant T2ᵢ. If, instead of a discrete sum of exponentials, the signal is assumed to be a distribution of T2 values, the sum over states can be represented by

S(t)=∫₀^{∞}A(1/T2)e^{-t/T2}d(1/T2) (5)

This has the same functional form as the ILT

F(t)=∫₀^{∞}A(s)e^{st}ds (6)

and can be treated as such. The ILT of an exponential function requires constraints to solve. A few methods that can be used to impose constraints are CONTIN, finite mixture modeling (FMM), and neural networks (NN). An inverse Laplace transform may also be used in the generation of a 3D data set. A 3D data set can be generated by collecting a time series of T2 decay curves and applying an inverse Laplace transform to each decay curve to form a 3D data set. Alternatively, a 2D inverse Laplace transform can be applied to a pre-assembled 3D data set to generate a transformed 3D data set describing the distribution of T2 times.

In a heterogeneous environment containing two phases, several different exchange regimes may be operative. In such an environment having two water populations (a and b), rₐ and r_{b} correspond to the relaxation rates of water in the two populations; ƒₐ and ƒ_{b} correspond to the fraction of nuclei in each phase; τₐ and τ_{b} correspond to residence time in each phase; and a=(1/τₐ)+(1/τ_{b}) corresponds to the chemical exchange rate. The exchange regimes can be designated as: (1) slow exchange: if the two populations are static or exchanging slowly relative to the relaxation rates rₐ and r_{b}, the signal contains two separate components, decaying with time constants T₂ₐ and T_{2b}; (2) fast exchange: if the rate for water molecules exchanging between the two environments is rapid compared to rₐ and r_{b}, the total population follows a single exponential decay with an average relaxation rate (rₐᵥ) given by the weighted sum of the relaxation rates of the separate populations; and (3) intermediate exchange: in the general case where there are two relaxation rates r₁ and r₂ with r₁ equal to rₐ in the slow exchange limit rₐ<r_{b}, Amp₁+Amp₂=1, and where r_{1,2} goes to the average relaxation rate in the fast exchange limit, equations 7, 8, 9, and 10 may be applied:

$$\begin{matrix}{r}_{1} = ( 1 / 2 ) ( {r}_{a} + {r}_{b} + a ) - ( 1 / 2 ) \sqrt{{( {r}_{b} - {r}_{a} + a )}^{2} - 4 {af}_{b} ( {r}_{b} - {r}_{a} )} & ( 7 ) \\ {r}_{2} = ( 1 / 2 ) ( {r}_{a} + {r}_{b} + a ) - ( 1 / 2 ) \sqrt{{( {r}_{b} - {r}_{a} + a )}^{2} - 4 {af}_{b} ( {r}_{b} - {r}_{a} )} & ( 8 ) \\ {Amp}_{1} = \frac{{r}_{2} - {r}_{av}}{{r}_{2} - {r}_{1}} & ( 9 ) \\ {Amp}_{2} = \frac{{r}_{av} - {r}_{1}}{{r}_{2} - {r}_{1}} & ( 10 )\end{matrix}$$

The device of the invention may also include the use of a pulsed field gradient or a fixed field gradient in the collection of relaxation rate data. The invention further features the use of the techniques of diffusion-weighted imaging (DWI) as described in Vidmar et al. (Vidmar et al., NMR Biomed. 23: 34-40 (2010)), which is herein incorporated by reference, or any methods used in porous media NMR (see, e.g, Bergman et al., Phys. Rev. E 51: 3393-3400 (1995), which is herein incorporated by reference). The devices of the invention can be equipped with a microchip programmed with an algorithm described herein for analysis of sample data.

The device also features a touch-screen LCD that can display device control parameters and results of the endotoxin analysis. The device can collect NMR relaxation measurements over a time period of 1 to 60 minutes, preferably 1 to 30 minutes.

### Disposable Cartridges

The invention features disposable cartridges that are sized to fit into the receiving slot of the portable device described above. The cartridge contains a top cover. This top cover is designed to move up and down and contains a single sample input port into which a liquid sample (e.g., a blood sample, or a pharmaceutical solution sample) is dispensed. The underside of the top cover also contains protrusions. The input port leads into a fluidic channel that dispenses a known volume of liquid sample into a sample chamber. The cartridge may have a single input port connected to multiple fluidic channels that dispense known volumes of liquid sample into a plurality of sample chambers (e.g., at least 3, 4, 5, 8, 10, 12, or 20 chambers) for side-by-side measurements, each sample chamber equipped with a particular combination of reagents (e.g., side-by-side comparisons including positive and/or negative controls). Alternatively, the cartridge may have a plurality of input ports connected via a plurality of fluidic channels to a plurality of sample chambers, allowing the dispensing and measurement of multiple samples under the same conditions in parallel without risk of cross-contamination between the samples.

The chambers may be vertically divided, by a frangible membrane seal, into two sections: a sample chamber and a testing chamber. The testing chamber contains the testing reagent. This design provides a mechanism to control when the sample and the testing reagents mix, and when NMR measurements start. In one aspect of the invention, the reagents may be endotoxin analysis reagents, e.g., a Factor-C containing reagent.

The chambers may have a volume of 1 μl to 150 μl, preferably about 20 μl (e.g., 10, 20, 30, 40, 60, 80 μl). This feature helps reduce the amount of testing reagent (e.g., LAL) that is required per reaction. The two chambered approach also allows for precise metering of the blood or sample volume without requiring careful pipetting by the user, because the volume of reagent introduced into the detection well will only be the volume that is in the chamber above the seal.

The top cover of the cartridge may contain protrusions, that when pushed down can break the frangible membrane seal and allow mixing of sample with testing reagents. For example, when the cartridge containing the sample is loaded into the device and the device lid is closed, this closing of the device lid can push the top cover of the cartridge down and results in the puncturing of the frangible membrane seal resulting in mixing of the sample and test reagents and simultaneous start of the reaction in multiple wells. Simultaneous start of the reaction in multiple wells enables the determination of reaction rate or point of equilibrium with multiple test reagents at the same time under the same environmental conditions.

Testing reagents can be deposited and dried on both the frangible membrane and within the test chamber. In this way it is possible to introduce two separate reagents to the sample. By way of non-limiting example, one could use the cartridge to produce a control for the LAL assay. An endtoxin can be dried on the membrane, which would be rehydrated by the addition of water to the cartridge. Then, when the chamber was pierced this sample would be introduced to the test chamber which contained the LAL and the coagulation reaction would occur. Another use is to introduce a first reagent, for example fibrinogen on the frangible membrane, and reptilase, factor XIIIa and arachidonic acid could be in the well. This would be useful for assessment of patient responsiveness to aspirin. A list of reagents contemplated is listed below.

As well as dried reagents, liquid reagents could also be contained within the cartridge. The reagent within the test chamber could be liquid phase if desired, allowing reagents that cannot be effectively lyophilized or dried down to be used on the cartridge.

### Interface of the Device and Cartridge, and Various Modifications of the Device and the Cartridge

The cartridge when inserted into the slot fits in a manner such that individual RF receiver coils surround each sample chamber. The RF receiver coils can be part of the device housing as described above, or disposable RF receiver coils may surround each chamber and may be part of the cartridge. In the latter case, the design of the cartridge and the device would be modified to include electrical connections to be made between the cartridge and the device when the cartridge is inserted into the device slot. The space between each of the RF coils can include shielding (e.g., aluminum shielding) to avoid cross-talk between the coils. Alternatively, analog switches that electrically connect one of the RF coils to the spectrometer, while shorting or actively compensating the other RF coils can be used to minimize cross-talk.

Depending on the number and size of samples in the cartridge, if the “sweet spot” of a single magnet is not large enough to define the magnet field, then multiple magnets can be used to permit each sample to be measured within a uniform magnetic field. Alternatively, the device could be equipped with a linear, motorized stage on which the cartridge is placed, permitting each test chamber to be moved into the position of the sweet spot prior to making a measurement. Interleaving NMR relaxation measurements between all of the reaction chambers with a short enough measurement time can be used to provide adequate temporal sampling for each test chamber. Optionally, multiple magnets, configured to produce multiple sweet spots, are used to accommodate multiple cartridges assayed simultaneously.

Precise control of the contact between the sample and the testing reagent is important for initiating the gelation/clotting reaction at a predetermined the starting time. As described above this can be achieved by closing the device lid which causes protrusions in the top of the cartridge to move down and break the seal between the sample and test chambers. The closing of the lid also activates a timer that starts the NMR measurements. The plungers could also be staggered to produce different reaction initiation times if this is required by the assay.

Alternatively, the device can be equipped with an actuator member that actuates breaking the seal between the sample and test chambers so that reactions can be started sometime after the lid is closed. The sample liquid may be held by capillary forces within a holding tube and then dispensed using an applied pressure (e.g., by using a pipette) in order to be mixed with the testing reagents. This approach may facilitate mixing by repeatedly aspirating and dispensing the fluid into the test chamber. In yet another aspect of the invention, the sample fluid may be held in a tube and then dispensed using a simple peristaltic pump design, which may be part of the device. Each of the above described methods provides a way to simultaneously start multiple reactions in a plurality of chambers.

The systems of the invention can also include one or more agitation units to create a more uniformly distributed gel or clot within the sample tube, or to ensure the assay reagents are adequately mixed within the sample tube. For example, the agitation units can include a sonication, vortexing, shaking, or ultrasound station for mixing one or more liquid samples. Mixing could be achieved by aspiration dispensing or other fluid motion (e.g., flow within a channel). Also, mixing could be provided by a vibrating pipette or a pipette that moves from side to side within the sample tube. For example, the agitation unit can be vortexer or a compact vortexer each of which can be designed to provide a stable motion for the desired sample mixing. The system can include an agitation unit for each cartridge, optionally, an agitation unit is provided for each chamber of the cartridge. In one particular approach, the agitation unit is a plunger for mixing, and optionally delivering, a sample or reagent to a test chamber. The plunger can be positioned to permit repeated uptake and expulsion of the chamber contents into the test chamber with a syringe-like action.

### Use of Cartridge and Device for Analysis of Changes in Rheological State of Samples

The cartridge and device described above may be used as follows: (i) a sample is dispensed into the input port of the cartridge; (ii) the cartridge is placed in the device and the lid is shut; (iii) the sample is mixed with testing reagent in the cartridge chambers, initiating a reaction; (iv) NMR measurements are made, either multiple measurements over a predetermined period of time (e.g., 1-30 minutes) or a single measurement at specific time, following the initiation of the reaction; (v) results are displayed (e.g., T2 relaxation signature curves, T2 values, or data comparing an observed result to a control value) characteristic of changes the rheological state of the sample; and, optionally, (vi) based upon the result, (a) the presence or absence of endotoxin in sample is determined, or (b) the coagulability (e.g., hypercoagulable, hypocoagulable, or normal) of a blood sample is determined.

### Endotoxin Testing Reagents

Testing reagents in the present invention may include an endotoxin analysis reagent, e.g., a Factor-C containing reagent. A suitable Factor C-containing reagent may be a horseshoe crab amebocyte lysate conventionally used for the Limulus test. Such a horseshoe crab amebocyte lysate is not particularly limited as long as it is derived from, for example, hemocytes of horseshoe crabs belonging to the Limulus sp., the Tachypleus sp. or the Carcinoscorpius sp., and it can produce the clotting enzyme via a reaction with endotoxin. Therefore, a commercially available Limulus reagent (LAL reagent), or a Limulus reagent (LAL reagent) provided in a kit for endotoxin measurement can be suitably used.

It is also possible to use a recombinant Factor C derived from a recombinant gene prepared based on all or a part of the horseshoe crab Factor C gene. A suitable example of the recombinant Factor C may be the recombinant Factor C provided in the commercially available PyroGene rFc (manufactured by Lonza Walkersville and Inc., distributed by Daiichi Pure Chemicals Co., Ltd.). Alternatively, the recombinant Factor C may be obtained by preparing an expression vector having the horseshoe crab Factor C gene inserted thereinto according to a known genetic engineering method, introducing the vector into appropriate host cells to achieve expression of a recombinant protein, and purifying the protein.

The chambers in the cartridge can process liquid sample volumes of 1 μl to 150 μl and thus allow the use of a reduced amount of C-containing reagent. When the horseshoe crab amebocyte lysate conventionally used in the Limulus test (for example, a commercially available Limulus reagent) as the Factor C-containing reagent, the amount used with the methods of the invention can be about 10% to 50% of the typical amount otherwise used. This is because of the increased sensitivity of the assay of the invention. About 10% to 50% of the typical amount is equivalent to approximately 0.375 to 2.2 mg/mL of protein derived from horseshoe crab amebocyte lysate.

The testing reagent may be present in the testing chamber of the cartridge, and may be present in liquid form or in lyophilized dry powder form. The testing reagent may be pre-packaged into the cartridge and the testing chamber sealed by a frangible membrane prior to shipping of the cartridge to the end user. Alternatively, the sample and testing reagent may be mixed by the user and loaded into the chambers of the cartridge, which is then inserted into the device for T2 measurements.

### Testing Reagents for Measuring Changes Rheological State of Blood Samples

Blood clotting initators and blood clotting inhibitors may be used as testing reagents for probing abnormalities in the blood clotting pathway of a subject. For example, in the kaolin activation pathway (CK pathway), citrated blood is treated with kaolin and this blood/kaolin sample is mixed with CaCl₂ initiator in the testing reagent. For the activator pathway (A pathway), heparinase treated blood sample can be mixed with activator solution (A-P1, PlateletMapping assay kit, Haemonetics) which is the testing reagent. For the activator+ADP pathway, heparinase treated blood sample can be mixed with a testing reagent which is a mix of A-P1 and ADP-P2 (ADP-P2, PlateletMapping assay kit, Haemonetics). The signal response observed under different activation conditions can be diagnostic of the hemostatic condition of a subject.

The devices of the invention can also be used to monitor and/or guide anticoagulant therapies or antiplatelet therapies. Antiplatelet therapy is increasingly being prescribed for primary and secondary prevention of cardiovascular disease to decrease the incidence of acute cerebro- and cardiovascular events. Antiplatelet drugs typically target to inhibit cyclooxygenase 1/thromboxaneA2 receptors (e.g., aspirin), adenosine diphosphate receptors (e.g., clopidogrel), or GPIIb/IIIa receptors (e.g., abciximab, tirofiban). Although antiplatelet drugs are thought to work primarily by decreasing platelet aggregation, they also have been shown to function as anticoagulants. Because platelets play a key role in overall coagulation, the assessment of the platelet function (more than their number) is critical in the perioperative setting. Anticoagulant therapies (e.g., rivaroxaban, dabigatran, among others) can be monitored for efficacy and compliance, and to ensure avoidance of adverse side effects and/or adverse events (e.g., bleeding events). Dosing adjustments for such therapies have been reported to control bleeding in large, randomized studies. Specifically, dosing of anticoagulants, including direct Factor Xa inhibitors can be used to assist maintenance of a therapeutic window and lead to a reduction of risk of stroke in atrial fibrillation and deep vein thrombosis in patients.

For this use, the testing reagent includes varying concentrations of the antiplatet or anticoagulant agent, which allows the patient response to the treatment to be assessed.

### Signature Curves Characteristic of Gelation or Clotting Process and Display of Signature Curves on LCD Screen

The device of the invention may optionally include data processing tools, and microprocessors that run algorithms to transform the raw relaxation NMR data into a format that provides signature curves characteristic of a gelation or clotting process, and presence of endotoxins in a sample. These curves can then be displayed on the touch-screen LCD. Possible transforms include the Laplace or inverse Laplace transform (ILT). The data for each T2 measurement may be transformed from the time dimension where signal intensity is plotted verses time to a “T2 relaxation” dimension. The ILT provides not only information about the different relaxation rates present in the sample and their relative magnitudes but also reports on the breadth of distribution of those signals.

Each acquired T2 relaxation curve has a corresponding two dimensional signature that maps all of the different populations of water, or different T2 relaxation environments, that water is experiencing in the sample. These curves can be compiled to form a 3D data set by stacking the plots over the duration of the gelation or clotting time dimension. This generates a topography that shows how the different populations of water change as a function of time.

The data gathered using the device of the invention can be represented using 3D plots generated from different NMR parameters and displayed on the LCD screen. Additional dimensions can be added by looking at specific patient types or clotting curve types. Data reduction methods can be used to simplify the complex information that is available. Such techniques as principal component analyses (PCA), automated feature extraction methods, or other data handling methods can be used. Ideally, a library of signatures, 2D, and 3D plots can be generated for a wide variety of clinical conditions. For example, two dimensional (intensity versus T2 value or T2 value versus time) or three dimensional representations (intensity versus T2 value versus time). The T2 values in the two- or three dimensional representation may be replaced with or compared to other NMR signals such as T1, T1/T2 hybrid, T₁ᵣₕₒ, T₂ᵣₕₒ and T₂*.

Alternatively, an endotoxin-induced gelation process within a sample is assessed by an NMR parameter extracted from one or more free induction decay (FID) signals obtained from the sample. For example, an NMR parameter can be extracted from the signal to noise ratio of an FID, from a comparison of an FID to a predetermined threshold, or from the integration of an FID. The NMR parameters obtained by the method can be used to characterize the gelation process, improve sensitivity, or reduce the amount of time needed to produce a test result. The devices of the invention can be equipped with a microchip programmed with an algorithm described herein for analysis of sample data.

The NMR parameters and test conditions used to identify samples testing positive for endotoxin can be those described in U.S. Provisional Application Ser. No. 61/576,607, filed Dec. 16, 2011, and incorporated herein by reference.

The NMR parameters and test conditions used to monitor blood clot formation can be those described in U.S. Provisional Application Ser. No. 61/625,945, filed Apr. 18, 2012, and incorporated herein by reference.

Display of 3D plots on LCD panel 3D representations of the T2 data in a sample undergoing a gelation or a clotting process may be generated using the methods of the invention. In certain embodiments, the dimensions of the generated 3D plots correspond to a relaxation time (e.g., T2 or 1/T2) dimension, an intensity or amplitude dimension, and a time dimension. The time dimension represents the time over which the gelation or clotting process has proceeded or is proceeding. The 3D plots obtained from endotoxin-induced gelation can exhibit a variety of topographical features that correspond with separate water populations in different physical and/or chemical environments within the sample. The 3D plots and the data used to generate the 3D plots may be mined for biomarkers or clotting behaviors associated with the sample. The 3D plots or the data used to generate the 3D data plots may also be used to discover new biomarkers.

The slope or curvature of a topographical feature of a 3D plot may be correlated with a gelation or clotting behavior. A cross-section of a 3D plot may also be used to calculate a gelation or clotting behavior. In particular, a cross-section showing T2 intensity as a function of time for a particular T2 time may be useful in calculating the gelation or clotting time (R) and/or fibrinolysis. A cross-section of a 3D plot showing T2 time as a function of intensity at a given time (a T2 relaxation spectrum) depicts the various water populations present in a sample at a given time. The features of a T2 relaxation spectrum can be mined for a range of gelation or clotting behaviors. For example, the difference between two signals in a T2 relaxation spectrum may be used to evaluate clot strength. The integration of a particular topographical feature, such as the volume of a particular feature, or curve from a cross-section of a 3D plot may also be useful in establishing a clotting behavior (e.g. clot strength). Gelation or clotting behaviors may also be extracted through the integration of a range of T2 relaxation spectra collected at sequential or disparate time points.

Alternatively, the 3D plots can be used to identify a feature characteristic of clot behavior. The feature can be one that is measured without 3D analysis, such as via pulse sequence for selectively monitoring a water population having an average T2 relaxation rate of about 400 milliseconds or 1,000 milliseconds at a particular time post clot initiation. Optionally, the water population is measured exclusive of other water populations in the sample.

Other Samples

The devices of the invention can be used to monitor theological changes in many types of liquid samples. The liquid samples do not need to be optically clear since no optical measurements are being performed. The samples may include, without limitation, whole blood, plasma, and endotoxin samples described here, or any turbid or opaque liquid sample. The samples can be from a human subject, or from a pharmaceutical solution or suspension.

The device and cartridge of the invention may be used for measurements of changes in viscosity, gelation, coagulation, and/or rheological changes in sample fluid, such as those changes characteristic of endotoxin analysis or blood clotting.

### OTHER EMBODIMENTS

All publications, patents, and patent applications mentioned in this specification are herein incorporated by reference to the same extent as if each independent publication or patent application was specifically and individually indicated to be incorporated by reference.

While the invention has been described in connection with specific embodiments thereof, it will be understood that it is capable of further modifications and this application is intended to cover any variations, uses, or adaptations of the invention following, in general, the principles of the invention and including such departures from the present disclosure that come within known or customary practice within the art to which the invention pertains and may be applied to the essential features hereinbefore set forth, and follows in the scope of the claims.

Other embodiments are within the claims.

What is claimed is:

1. A disposable cartridge sized for convenient insertion into and removal from a slot of a portable magnetic resonance device comprising:
a) a plurality of chambers, wherein for each of the plurality of chambers the chamber comprises (i) a sample chamber, (ii) a test chamber, and (iii) a barrier separating the sample chamber and the test chamber, wherein for at least one test chamber among the plurality of chambers comprises a testing reagent;
b) a sample input port for receiving a liquid sample, wherein for one or more of the plurality chambers, the sample input port is in fluid communication with the sample chamber; and
c) a top cover for holding the plurality of chambers, wherein for each of said the plurality of chambers the top cover includes a moveable member, wherein movement of the moveable member from a first position to a second position opens the barrier and mixes the contents of the sample chamber and the test chamber.

2. The cartridge of claim 1, wherein the sample input port is connected to each of the plurality of chambers by a fluidic channel configured to distribute equal volume of sample from the input port into each sample chamber.

3. The cartridge of claim 1, comprising a plurality of sample input ports for receiving a plurality of samples, wherein for each of the plurality of sample input ports a single sample input port is connected to a single sample chamber by a fluidic channel.

4. The cartridge of claim 1, further comprising a reservoir for holding a testing reagent, wherein the reservoir is in fluid communication with one or more of the plurality of chambers.

5. The cartridge of claim 4, wherein the reservoir is connected to a single sample chamber by a fluidic channel which is configured to permit passage of the testing reagent into the sample chamber at a predetermined time.

6. The cartridge of claim 1, wherein said testing reagent is a limulus amoebocyte lysate.

7. The cartridge of claim 1, wherein said testing reagent is a blood clotting initiator or a blood clotting inhibitor.

8. The cartridge of claim 1, wherein, each of said plurality of sample chambers has a volume of from 1 μT to 150 pL.

9. The cartridge of claim 1, further comprising a lid, wherein for each of said plurality of sample chambers closing of said lid results in a movement of said moveable member to a position causing said barrier to open.

10. The cartridge of claim 1, wherein a frangible membrane seal separates the sample chamber and the test chamber, and wherein movement of the moveable member from a first position to a second position breaks the frangible membrane seal and mixes the contents of the sample chamber and the test chamber.

11. The cartridge of claim 10, wherein said moveable member comprises a protrusion for puncturing said frangible membrane.

12. The cartridge of claim 10, wherein said moveable member comprises a plunger for applying pressure to and breaching said frangible membrane.

13. The cartridge of claim 10, wherein a first testing reagent is immobilized on the frangible membrane and a second testing reagent is located within the test chamber.

14. A portable magnetic-resonance device for measuring a change in the rheological state of a sample, the device comprising:
a) a permanent magnet defining a magnetic field;
b) an RF excitation coil for transmitting an RF excitation to a plurality of liquid samples;
c) a slot for receiving a cartridge of claim 1, said cartridge comprising a plurality of liquid samples;
d) for each said liquid samples an RF coil disposed about the liquid sample and configured to detect an NMR relaxation response produced by exposing the liquid sample to a bias magnetic field created using the permanent magnet and the RF excitation;
e) a timer;
f) a lid; and
g) optionally, a touch-screen LCD panel for displaying device control parameters and/or test results.

15. The device of claim 14, wherein said cartridge comprises a) a plurality of chambers, wherein for each of the plurality of chambers the chamber comprises (i) a sample chamber, (ii) a test chamber, and (iii) a barrier separating the sample chamber and the test chamber, wherein for at least one test chamber among the plurality of chambers comprises a testing reagent; and said timer is configured to be activated when said barrier is opened.

16. The device of claim 15, wherein activation of said timer initiates measurement of a NMR relaxation response characteristic of a change in a rheological state of said liquid sample.

17. The device of claim 16, wherein said liquid sample is whole blood, plasma, or any turbid, opaque, or clear liquid sample.

18. The device of claim 15, wherein the RF coil disposed about the liquid sample is configured to serve as the RF excitation coil.

19. The device of claim 14, wherein, for each of the chambers, the RF coil disposed about the liquid sample is contained within the cartridge.

20. The device of claim 14, wherein, for each of the chambers, the RF coil disposed about the liquid sample is not contained within the cartridge.

21. The device of claim 14, further comprising a heater for heating one or more of the plurality of chambers.

22. The device of claim 14, wherein said device is used to measure changes in viscosity, gelation, coagulation, and rheological state of said liquid sample.
